(19) United States
(12) Patent Application Publication
(10) Pub. No.: US 2025/0349619 A1
(43) Pub. Date: Nov. 13, 2025

(54) Method for Attaching Metallic Bodies to Thin Semiconductor Dies at Wafer Level

(71) Applicant: Infineon Technologies AG, Neubiberg (DE)

(72) Inventors: Christoph Bayer, Eußenheim (DE); Francisco Javier Santos Rodriguez, Villach (AT); Olaf Rüdiger Hohlfeld, Warstein (DE)

(21) Appl. No.: 18/661,044

(22) Filed: May 10, 2024

(51) Int. Cl. H01L 21/78; H01L 21/56; H01L 23/00; H01L 23/31

(52) U.S. Cl. CPC H01L 21/78; H01L 21/561; H01L 23/3107; H01L 24/83; H01L 24/96; H01L 2224/8382; H01L 2224/8384; H01L 2224/96; H01L 2924/13055; H01L 2924/13062; H01L 2924/13064; H01L 2924/13091

(57) ABSTRACT

A method includes providing a semiconductor wafer having a thickness of 250 microns or less. The semiconductor wafer includes a plurality of die sites each including a vertical power semiconductor device. The method further includes attaching a metallic wafer to the semiconductor wafer. The metallic wafer has a similar shape as the semiconductor wafer. Before or after attaching the metallic wafer to the semiconductor wafer, the die sites of the semiconductor wafer are singulated into individual semiconductor dies. After attaching the metallic wafer to the semiconductor wafer but before removing the individual semiconductor dies from the semiconductor wafer, the metallic wafer is singulated into a plurality of separate metallic bodies that remain attached to the individual semiconductor dies.

### BACKGROUND

Demand for electronic components for power applications continues to increase rapidly across a wide range of industries, including automotive, consumer electronics, renewable energy, manufacturing, and medical, among many others. Developments in semiconductor materials such as silicon carbide (SiC) and gallium nitride (GaN) have enabled power electronic devices with advantageous features such as smaller footprint, higher voltage and current capabilities, and faster switching speeds. In some instances, however, performance gains that are provided by the semiconductor technology may not be fully realized when integrating the respective power semiconductor devices (e.g., chips or dies) into components, modules, or other assemblies due to limitations in packaging and connection technologies. For example, operating currents of power semiconductor devices that may be achieved in an assembly may be limited by connections that are used to electrically couple the power semiconductor devices to a substrate (e.g., a lead frame, a printed circuit board) rather than the devices themselves. Additionally, dissipation of heat associated with high currents through the power semiconductor devices in some applications may be limited by heat dissipation capabilities of the assembly, thus limiting the current that may be passed through the power semiconductor devices without exceeding the thermal limits of the assembly. Finally, dimensions of the power semiconductor devices such as die thickness may be constrained by the handling that is required to integrate them into a component, module, or other assembly. Specifically, handling of thinner dies (e.g., less than 250 microns) may be difficult and at risk for damage using current packaging technologies.

Thus, there is a need for a solution that improves the integration of power semiconductor devices, particularly thin power semiconductor dies, into power semiconductor components, modules, and assemblies.

### SUMMARY

According to an embodiment of a method for attaching metallic bodies to thin semiconductor dies at the wafer level, the method comprises: providing a semiconductor wafer comprising a plurality of die sites each including a vertical power semiconductor device, the semiconductor wafer having a thickness of 250 microns or less; attaching a metallic wafer to the semiconductor wafer, the metallic wafer having a similar shape as the semiconductor wafer; before or after attaching the metallic wafer to the semiconductor wafer, singulating the die sites into individual semiconductor dies; and after attaching the metallic wafer to the semiconductor wafer but before removing the individual semiconductor dies from the semiconductor wafer, singulating the metallic wafer into a plurality of separate metallic bodies that remain attached to the individual semiconductor dies.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A-1C illustrate a semiconductor wafer and a metallic wafer used in a method for attaching metallic bodies to thin semiconductor dies at the wafer level, according to an embodiment.

FIGS. 2A-2C illustrate side views of the semiconductor wafer in a method for attaching metallic bodies to thin semiconductor dies at the wafer level, according to an embodiment.

FIGS. 3A-3C illustrate attaching the metallic wafer to the semiconductor wafer in a method for attaching metallic bodies to thin semiconductor dies at the wafer level, according to an embodiment.

FIG. 4 illustrates applying an encapsulant in a method for attaching metallic bodies to thin semiconductor dies at the wafer level, according to an embodiment.

FIG. 5 illustrates singulating the metallic wafer into a plurality of separate metallic bodies in a method for attaching metallic bodies to thin semiconductor dies at the wafer level, according to an embodiment.

FIG. 6 illustrates removing an individual semiconductor die from the semiconductor wafer in a method for attaching metallic bodies to thin semiconductor dies at the wafer level, according to an embodiment.

FIGS. 7A-7B illustrate placing the individual semiconductor die from the semiconductor wafer on a power semiconductor module in a method for attaching metallic bodies to thin semiconductor dies at the wafer level, according to an embodiment.

FIG. 8 illustrates attaching a second metallic wafer to the semiconductor wafer in a method for attaching metallic bodies to thin semiconductor dies at the wafer level, according to an embodiment.

FIG. 9 illustrates singulating the second metallic wafer into a plurality of separate metallic bodies in a method for attaching metallic bodies to thin semiconductor dies at the wafer level, according to an embodiment.

FIGS. 10A-10B illustrate removing an individual semiconductor die from the semiconductor wafer in a method for attaching metallic bodies to thin semiconductor dies at the wafer level, according to an embodiment.

FIGS. 11A-11B illustrate placing the individual semiconductor die from the semiconductor wafer on a power semiconductor module in a method for attaching metallic bodies to thin semiconductor dies at the wafer level, according to an embodiment.

### DETAILED DESCRIPTION

Described herein is a method for pre-packaging thin (less than 250 microns) power semiconductor devices at the wafer level for subsequent integration into power semiconductor modules or other assemblies. Specifically, the method includes attaching a metallic wafer to one or both sides of a thin semiconductor wafer. The metallic wafer may include a plurality of distinct metallic bodies that are attached to terminals of vertical power semiconductor devices of the semiconductor wafer during processing, or may be a planar metallic wafer with no defined features. The semiconductor wafer may be in a presingulated state or may be partially or completely singulated into individual semiconductor dies. After attaching the metallic wafer to the semiconductor wafer, the metallic wafer is singulated into a plurality of individual metallic bodies that remain attached to the individual semiconductor dies. The metallic body or bodies that remain attached to the individual semiconductor dies may form contacts for one or more terminals of power semiconductor devices realized from the semiconductor dies. Each individual semiconductor die of the semiconductor wafer may then by transferred to an assembly such as a module, e.g., using a pick and place tool that contacts a metallic body that is attached to a respective individual semiconductor die and placing and attaching the semiconductor die and/or the metallic body to the assembly (e.g., to a substrate of the assembly).

The method described herein may offer a number of advantages when compared to other methods of integrating thin power semiconductor dies into assemblies such as power semiconductor modules. For example, handling of individual thin semiconductor dies may be reduced by attaching the metallic bodies of a metallic wafer to the semiconductor dies at the wafer level. The metallic bodies from the metallic wafer may provide mechanical support to the thin semiconductor dies and may reduce damage to and/or breakage of the thin semiconductor dies during subsequent handling, such as when transferring them to a module or other assembly. Reducing the likelihood of die damage and breakage should increase manufacturing yields and enable thinner semiconductor dies to be used (e.g., less than 250 microns, less than 160 microns, or even less than 110 microns), potentially enabling device designs that offer higher performance. Additionally, the method described herein may eliminate the need to place the individual semiconductor dies on a base substrate that does not contribute to the function of the device since the method includes transferring the individual semiconductor dies and the attached metallic body (or bodies) directly to a module or other assembly. The metallic bodies of the metallic wafer may provide their own thermal and/or electrical benefits to the vertical power semiconductor devices, e.g., providing larger contact area for wire bonds and heat sinking. The shape and structure of the metallic bodies of the metallic wafer may be customized for optimal current and heat dissipation for a given vertical power semiconductor device design, and thus the method described herein may provide flexibility for a variety of power semiconductor device designs and layouts to be integrated into standard modules, components, and assemblies. Furthermore, the method described herein uses standard packaging and manufacturing methods such as wafer bonding techniques (e.g., soldering, sintering), wafer singulation and subsequent handling of singulated wafers, and pick and place of the individual semiconductor dies.

Described next, with reference to the figures, are exemplary embodiments of a method for attaching metallic bodies to thin semiconductor dies at the wafer level.

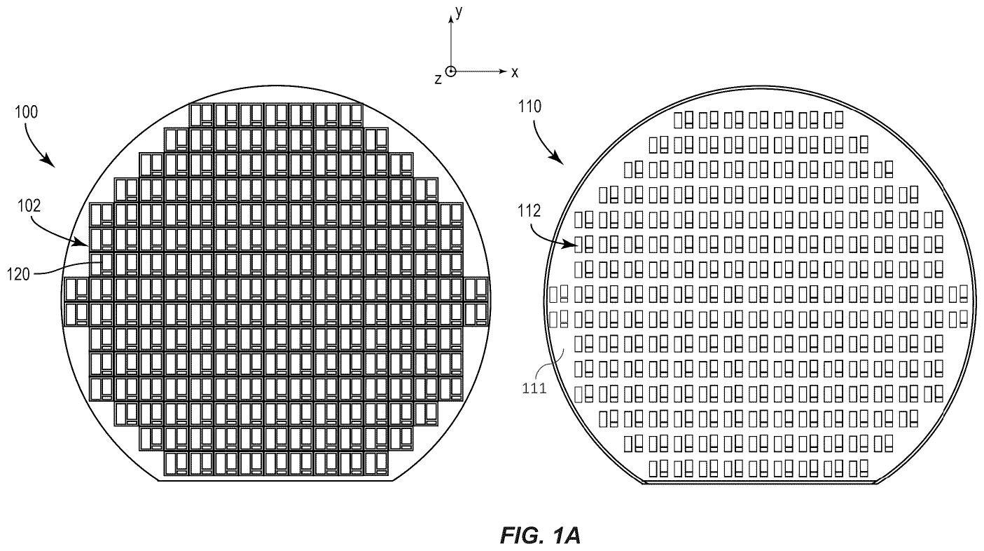

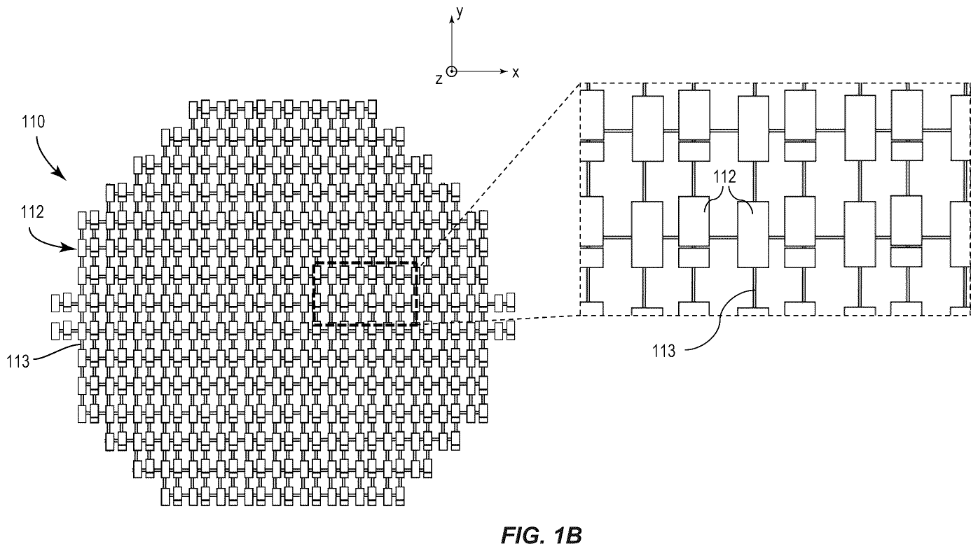

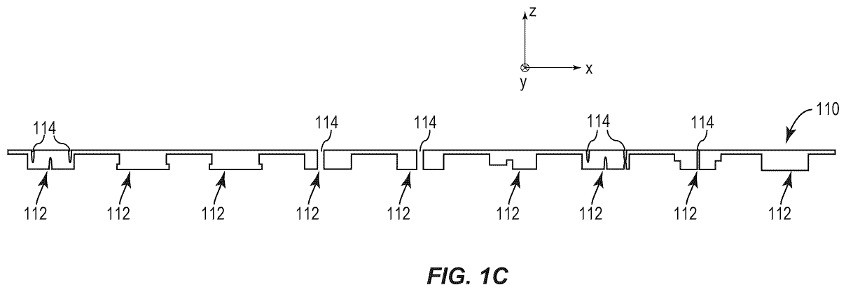

FIGS. 1A-1C illustrate a semiconductor wafer 100 and a metallic wafer 110 used in a method for attaching metallic bodies to thin semiconductor dies at the wafer level, according to an embodiment.

FIG. 1A illustrates top views of the semiconductor wafer 100 and the metallic wafer 110. The semiconductor wafer 100 is a thin wafer having a thickness of 250 microns or less. In some examples, the semiconductor wafer 100 may have a thickness of 160 microns or less, or even 110 microns or less. For example, the semiconductor wafer 100 may be a wafer that has been processed through a thinning process at the wafer backside, e.g., CMP (chemical mechanical polishing), grinding, etching, etc. A thickness of the semiconductor wafer 100 may include the thickness of the semiconductor material (e.g., Si, SiC, GaN, etc.) used to implement electrical devices such as transistors, diodes, etc. and the thickness of any layers formed on the semiconductor material such as one or more metallization layers, one or more interlayer dielectrics, one or more passivation layers, etc. In some examples, the semiconductor material may have a thickness of less than 10 microns, for example about 6 microns or less, and the thickness of the semiconductor wafer 100 may have a thickness of less than 250 microns, less than 160 microns, or less than 110 microns.

The semiconductor wafer 100 includes a plurality of die sites 102. Each die site 102 includes a vertical power semiconductor device 120. For each vertical power semiconductor device 120, the primary current flow path is between the front and back sides of the corresponding die site 102 (along the z direction in FIG. 1A). In one embodiment, some or all of the vertical power semiconductor devices 120 may be vertical power transistors such as SiC or GaN power MOSFETs (metal-oxide-semiconductor field-effect transistors). One or more of the vertical power semiconductor devices 120 may be a Si power MOSFET, HEMT (high-electron mobility transistor), IGBT (insulated-gate bipolar transistor), JFET (junction field-effect transistor), diode, etc. The vertical power semiconductor devices 120 of the semiconductor wafer 100 may all be of a similar or identical design (e.g., device type, structure, materials, dimensions, etc.), or some or each of the vertical power semiconductor devices 120 may have different designs. Various arrangements of designs of the vertical power semiconductor devices 120 on the semiconductor wafer 100 are contemplated. While FIG. 1A illustrates a single vertical power semiconductor device 120 for each die site 102, examples in which one or more die sites 102 each include two or more vertical power semiconductor devices 120 are contemplated.

The metallic wafer 110 has a similar shape as the semiconductor wafer 100. In the examples of FIGS. 1A-1C, the metallic wafer 110 includes a plurality of distinct metallic bodies 112, although examples in which the metallic wafer 110 is not structured with distinct metallic bodies are contemplated (e.g., a planar metallic wafer 110). The metallic bodies 112 of the metallic wafer 110 may be provided in a layout that corresponds to (e.g., mirrors) a layout of the die sites 102 and/or the vertical power semiconductor devices 120 (e.g., contact pads of the vertical power semiconductor devices 120) of the semiconductor wafer 100.

In the example of FIG. 1A, the metallic wafer 110 is a solid metallic piece 111 comprising the plurality of distinct metallic bodies 112 formed in the solid metallic piece 111. FIG. 1B illustrates a top view of an alternative example of the metallic wafer 110 in which the plurality of distinct metallic bodies 112 is interconnected via a web framework 113 rather than being formed of a solid metallic piece as in FIG. 1A.

The metallic wafer 110 may be formed from a sheet, plate, or other body of a metal or metal alloy. For example, the metallic wafer 110 may be formed from a sheet of copper, aluminum, a conductive alloy, etc. The sheet, plate, or other body may be stamped, etched, punched, or otherwise processed to produce the arrangement of the distinct metallic bodies 112, the web framework 113 (in the example of FIG. 1B), and any other features of the metallic wafer 110. The metallic wafer 110 may have a thickness that is greater than 50 microns. In some examples, the metallic wafer 110 has a thickness that is greater than 100 microns, e.g., up to 500 microns.

FIG. 1C illustrates a cross-sectional side view of part of the metallic wafer 110. FIG. 1C illustrates various exemplary structures of the distinct metallic bodies 112 of the metallic wafer 110. Such structures may, in some examples, provide thermal and/or thermo-mechanical advantages when attached to the semiconductor wafer 100, such as to a vertical power semiconductor device 120, e.g., of FIG. 1A. In some examples, the structures of the metallic bodies 112 that are illustrated may provide benefits such as improved attachment to the semiconductor wafer 100. Some of the metallic bodies 112 of the metallic wafer 110 include one or more vacuum openings (ports) 114 that extend at least partly through the metallic body 112. The vacuum opening(s) 114 may provide improved suction (e.g., from a vacuum duct) during a pick and place process. While the metallic bodies 112 of FIG. 1C each have different structures, this is only done to illustrate multiple possible structures. The metallic wafer 110 of any of the examples disclosed herein may include metallic bodies 112 having only one of these structures or a combination of two or more of these structures. Structures that are not illustrated and their combinations with structures that are illustrated herein are also contemplated. For simplicity, the remaining illustrations of the present disclosure will illustrate the metallic wafer 110 having a single structure of the metallic bodies 112.

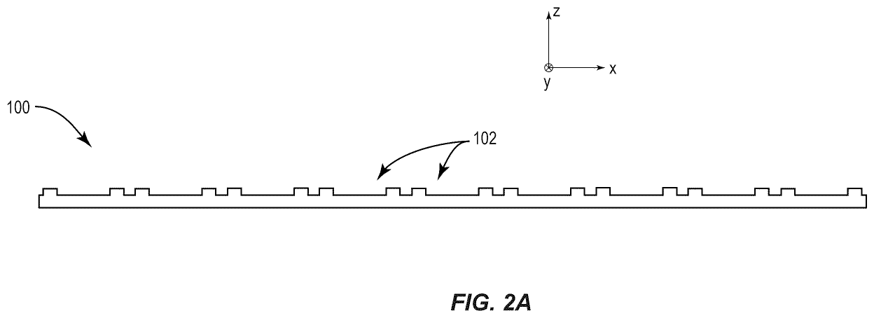

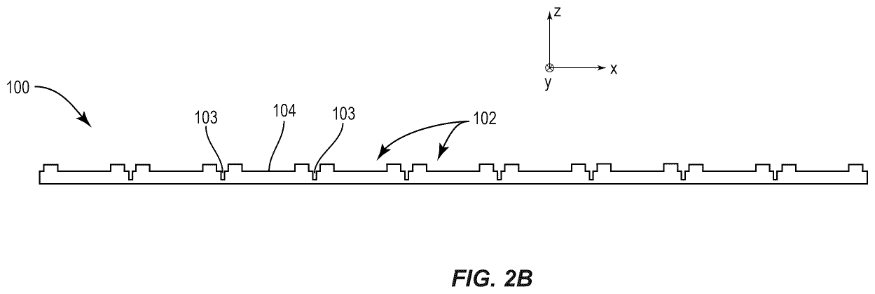

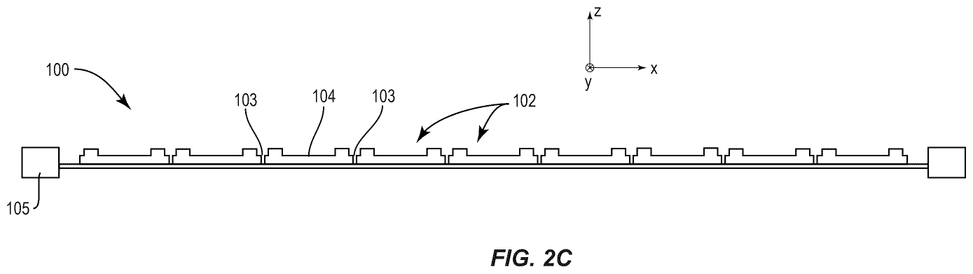

FIGS. 2A-2C illustrate side views of the semiconductor wafer 100 in a method for attaching metallic bodies to thin semiconductor dies at the wafer level, according to an embodiment.

FIG. 2A illustrates a side view of the semiconductor wafer 100 before singulation into individual semiconductor dies in a method for attaching metallic bodies to thin semiconductor dies at the wafer level, according to an embodiment. The semiconductor wafer 100 is illustrated as a continuous wafer comprising the plurality of the die sites 102.

FIG. 2B illustrates a side view of the semiconductor wafer 100 after partial singulation into individual semiconductor dies 104 in a method for attaching metallic bodies to thin semiconductor dies at the wafer level, according to an embodiment. The die sites 102 of the semiconductor wafer 100 of FIG. 2B are partially singulated into the individual semiconductor dies 104. A trench 103 (e.g., from a saw) extends partially through the semiconductor wafer 100 between each die site 102 to define the individual semiconductor dies 104.

FIG. 2C illustrates a side view of the semiconductor wafer 100 after complete singulation into individual semiconductor dies 104 in a method for attaching metallic bodies to thin semiconductor dies at the wafer level, according to an embodiment. The dies sites 102 of the semiconductor wafer 100 of FIG. 2C are completely singulated into the individual semiconductor dies 104. The trench 103 extends completely through the semiconductor wafer 100 between each die site 102 to define the individual semiconductor dies 104. The individual semiconductor dies 104 of the semiconductor wafer 100 may be suspended by a frame 105 or other structure comprising tape, foil, or by other means of supporting the individual semiconductor dies 104 in the shape of the semiconductor wafer 100 for subsequent processing.

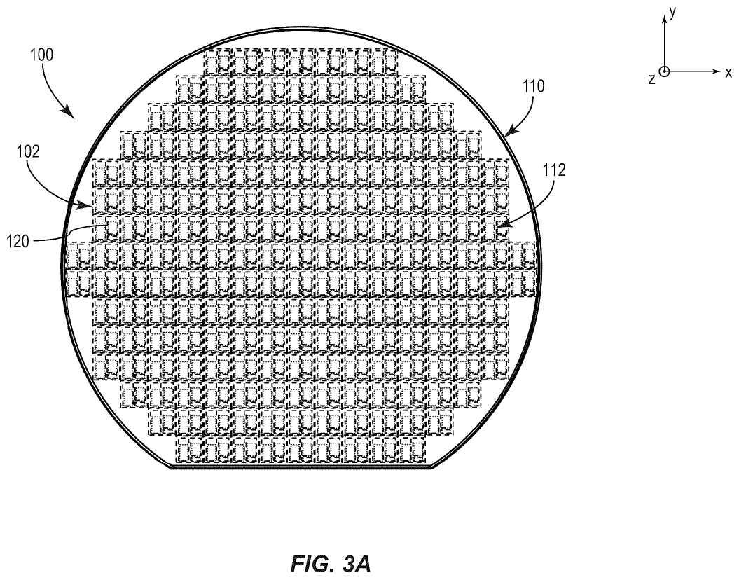

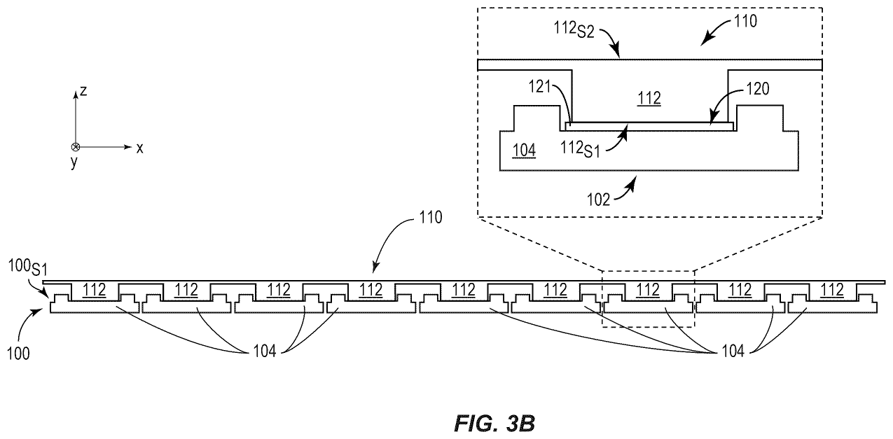

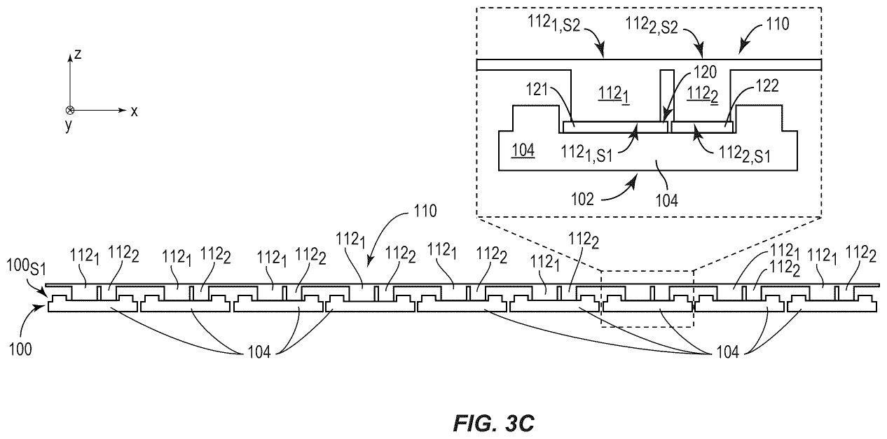

The subsequent steps illustrate the semiconductor wafer 100 in the completely singulated state as illustrated in FIG. 2C (e.g., optionally supported on the frame 105). However, the semiconductor wafer 100 of the following examples may be processed through any of the steps illustrated in subsequent FIGS. 3A-5 in the unsingulated or partially singulated states as illustrated in FIGS. 2A and 2B, respectively.

FIGS. 3A-3C illustrate attaching the metallic wafer 110 to the semiconductor wafer 100 in a method for attaching metallic bodies to thin semiconductor dies at the wafer level, according to an embodiment.

FIG. 3A illustrates a top view of the metallic wafer 110 aligned with the semiconductor wafer 100. For example, outer perimeters of the metallic wafer 110 and the semiconductor wafer 100 may be aligned. In examples where the metallic wafer 110 includes a plurality of distinct metallic bodies 112, one or more distinct metallic bodies 112 of the metallic wafer 110 may be aligned with each die site 102, individual semiconductor die 104, and/or vertical power semiconductor device 120 of the semiconductor wafer 100.

FIG. 3B illustrates a side view of attaching the metallic wafer 110 to a first side 100_{S1} of the semiconductor wafer 100. Attaching the metallic wafer 110 to the semiconductor wafer 100 includes attaching a first contact surface 112_{S1} of a distinct metallic body 112 of the metallic wafer 110 to a first load terminal 121 of the vertical power semiconductor device 120 of each die site 102. A second contact surface 112_{S2} opposite the first contact surface 112_{S1} of each metallic body 112 forms a contact for the first load terminal 121 of the vertical power semiconductor device 120 that is attached to the metallic body 112. The first load terminal 121 of the vertical power semiconductor device 120 of each die site 102 may be one of a source terminal, an emitter terminal, a drain terminal, or a collector terminal, e.g., of a MOSFET, an IGBT, a HEMT, a JFET, etc.

FIG. 3C illustrates a side view of attaching the metallic wafer 110 to a first side 100_{S1} of the semiconductor wafer 100. In this example, attaching the metallic wafer 110 to the semiconductor wafer 100 includes attaching a first contact surface 112_{1,S1} of a first metallic body 112₁ of the metallic wafer 110 to a first load terminal 121 of the vertical power semiconductor device 120 of each die site 102 and attaching a first contact surface 112_{2,S1} of a second metallic body 112₂ of the metallic wafer 110 to a control terminal 122 of the vertical power semiconductor device 120 of each die site 102. A second contact surface 112_{1,S2} opposite the first contact surface 112_{1,S1} of each first metallic body 112₁ forms a contact for the first load terminal 121 of the vertical power semiconductor device 120 attached to the first metallic body 112₁. A second contact surface 112_{2,S2} opposite the first contact surface 112_{2,S1} of each second metallic body 112₂ forms a contact for the control terminal 122 of the vertical power semiconductor device 120 attached to the second metallic body 112₂. The first load terminal 121 of the vertical power semiconductor device 120 of each die site 102 may be one of a source terminal, an emitter terminal, a drain terminal, or a collector terminal, e.g., of a MOSFET, an IGBT, a HEMT, a JFET, etc. The control terminal 122 of the vertical power semiconductor device 120 of each die site 102 may be a gate terminal.

Attaching the metallic wafer 110 to the semiconductor wafer 100 in the examples of FIGS. 3A-3C may include at least one of sintering, diffusion soldering, soldering, welding, adhering, gluing, etc. For example, a metallic body 112, 112₁, and/or 112₂ may be sintered, diffusion soldered, soldered, adhered, glued, etc. to the first load terminal 121, the control terminal 122, or another terminal of a vertical power semiconductor device 120.

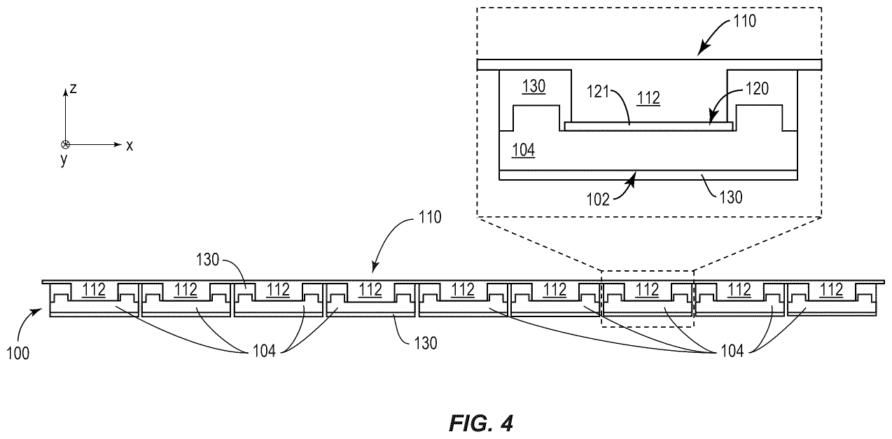

FIG. 4 illustrates applying an encapsulant 130 in a method for attaching metallic bodies to thin semiconductor dies at the wafer level, according to an embodiment. The encapsulant 130 is optional and is not a requirement of the method described herein. The encapsulant 130 may be applied after attaching the metallic wafer 110 to the semiconductor wafer 100 but before removing the individual semiconductor dies 104 from the semiconductor wafer 100. The encapsulant 130 may be applied such that it encapsulates at least a part of each die site 102, e.g. part or all of a vertical power semiconductor device 120 and part of a metallic body 112 such that a contact surface of the metallic body 112 (e.g., the second contact surface 112_{S2} of FIG. 3B, the second contact surfaces 112_{1,S2}, 112_{2,S2} of FIG. 3C) is exposed from the encapsulant 130.

The encapsulant 130 may be a mold compound. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc.

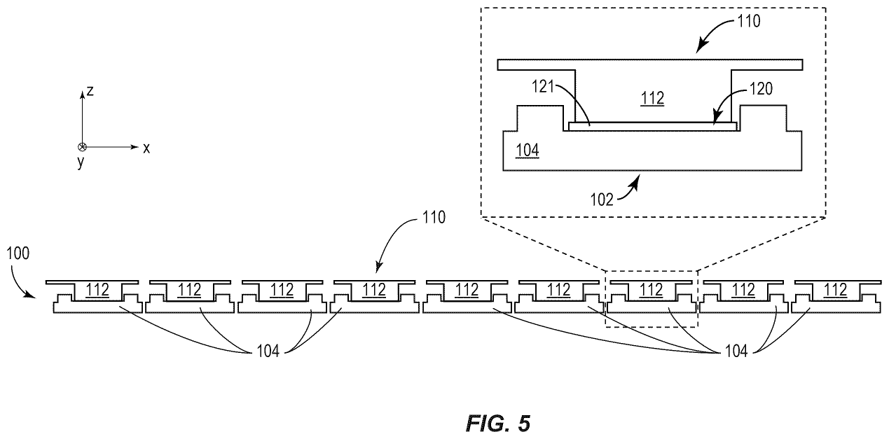

FIG. 5 illustrates singulating the metallic wafer 110 into a plurality of separate metallic bodies 112 in a method for attaching metallic bodies to thin semiconductor dies at the wafer level, according to an embodiment. The separate metallic bodies 112 remain attached to the individual semiconductor dies 104 of the semiconductor wafer 100 after singulating the metallic wafer 110. In examples where two or more metallic bodies 112 of the metallic wafer 110 are attached to a single individual semiconductor die 104 (e.g., the metallic bodies 112₁ and 112₂ of FIG. 3C), the two or more metallic bodies 112 may be singulated into two or more separate metallic bodies 112 that remain attached to the single individual semiconductor die 104 at this step.

Singulating the metallic wafer 110 may be done by sawing, e.g., mechanical sawing or laser sawing, by etching, etc. In some examples, singulating the die sites 102 of the semiconductor wafer 100 into individual semiconductor dies 104 and singulating the metallic wafer 110 into the plurality of separate metallic bodies 112 that remain attached to the individual semiconductor dies 104 are done simultaneously during the same singulation process (e.g., using the same saw, e.g., different dicing wheels of a single sawing tool). In some other examples, the semiconductor wafer 100 and the metallic wafer 110 may be singulated by different processes. For example, the one of the two wafers could be singulated via laser sawing and the other wafer by mechanical sawing. It is also contemplated that these two processes could be performed by a single tool (e.g., one which can perform both laser sawing and mechanical sawing) or by individual tools.

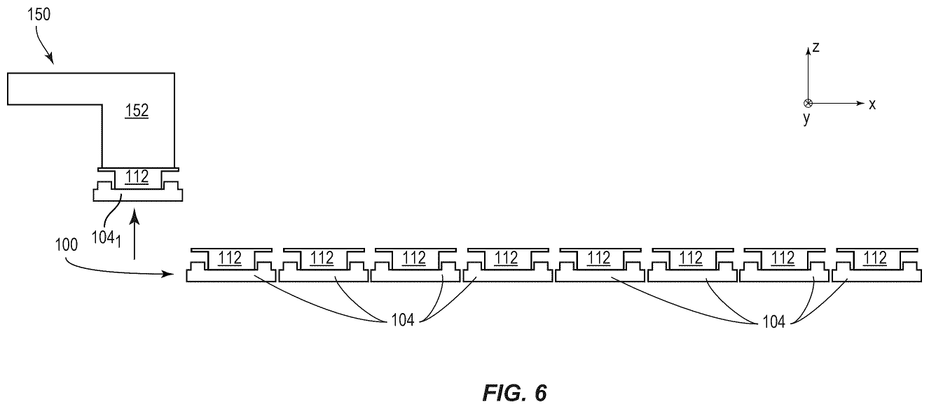

FIG. 6 illustrates removing an individual semiconductor die 104₁ from the semiconductor wafer 100 in a method for attaching metallic bodies to thin semiconductor dies at the wafer level, according to an embodiment.

One or more of the individual semiconductor dies 104 (e.g., the individual semiconductor die 104₁) may be picked and removed from the semiconductor wafer 100 after singulating the die sites 102 into individual semiconductor dies 104 and after singulating the metallic wafer 110 into the plurality of separate metallic bodies 112 that remain attached to the individual semiconductor dies 104. FIG. 6 illustrates picking the individual semiconductor die 104₁ by contacting the metallic body 112 attached to the individual semiconductor die 104₁ with a component 152 of a pick and place machine 150 and removing the individual semiconductor die 104₁ from the semiconductor wafer 100. The pick and place machine 150 may use suction (e.g., a vacuum through the component 152), an adhesive material on the component 152, or another means for attaching the component 152 of the pick and place machine 150 to the metallic body 112 of the individual semiconductor die 104₁ such that the individual semiconductor die 104₁ may be lifted from the semiconductor wafer 100. More than one semiconductor die 104 may be picked and placed at the same time.

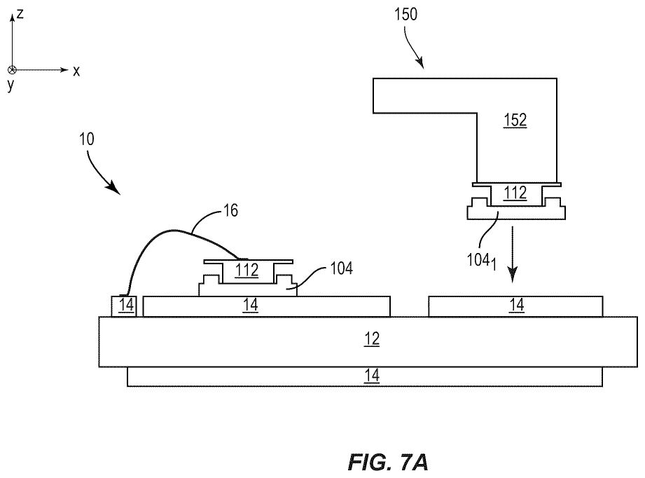

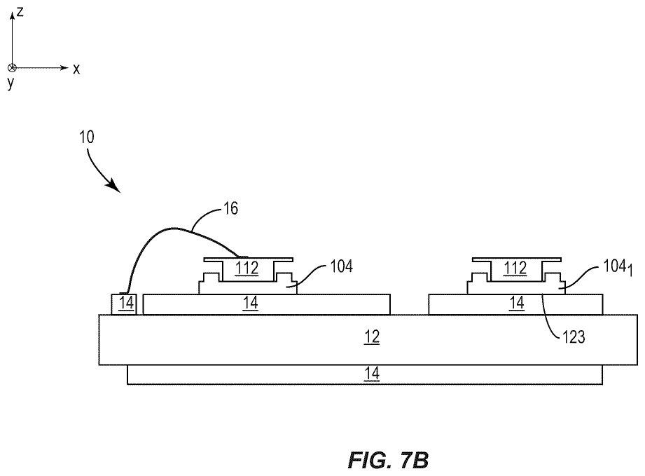

FIGS. 7A-7B illustrate placing the individual semiconductor die 104₁ from the semiconductor wafer 100 on a power semiconductor module 10 in a method for attaching metallic bodies to thin semiconductor dies at the wafer level, according to an embodiment.

The power semiconductor module 10 includes a substrate 12 having one or more metallization layers 14. The substrate 12 may be a printed circuit board (PCB), an insulated metal substrate (IMS), a DCB (direct copper bonded) substrate, an AMB (active metal brazed), a lead frame, etc. FIGS. 7A and 7B illustrate an individual semiconductor die 104 (e.g., from the semiconductor wafer 100, from a different semiconductor wafer) that has already been attached to a metallization layer 14 of the power semiconductor module 10. A metallic body 112 (e.g., of the metallic wafer 110) is attached to the individual semiconductor die 104 that is attached to the metallization layer 14. A wire bond 16 attaches the metallic body 112 that is attached to the individual semiconductor die 104 to a different metallization layer 14 of the power semiconductor module 10.

FIG. 7A illustrates placing, with the pick and place machine 150, the individual semiconductor die 104₁ on a metallization layer 14 of the power semiconductor module 10. FIG. 7B illustrates attaching the individual semiconductor die 104₁ to the metallization layer 14 of the power semiconductor module 10. In some examples, a second load terminal 123 of the individual semiconductor die 104₁ is attached to the metallization layer 14 of the power semiconductor module 10. The second load terminal 123 may be one of a source terminal, an emitter terminal, a drain terminal, or a collector terminal. In some examples, the individual semiconductor die 104₁ may be attached to the metallization layer 14 of the power semiconductor module 10 by diffusion soldering, soldering, or sintering (e.g., the second load terminal 123 to the metallization layer 14).

The methods of FIGS. 6-7B may be repeated for additional individual semiconductor dies 104 of the semiconductor wafer 100. Each additional individual semiconductor die 104 may be placed on the power semiconductor module 10 or another module, assembly, structure, etc.

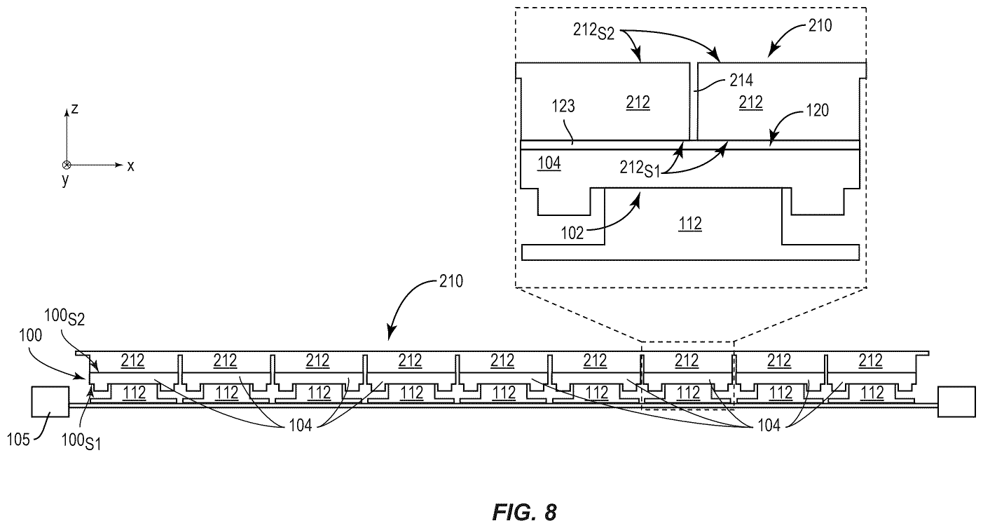

FIG. 8 illustrates attaching a second metallic wafer 210 to the semiconductor wafer 100 in a method for attaching metallic bodies to thin semiconductor dies at the wafer level, according to an embodiment.

The second metallic wafer 210 may be similar to the metallic wafer 110. Specifically, the second metallic wafer 210 includes a plurality of distinct metallic bodies 212, although examples in which the second metallic wafer 210 is not structured with distinct metallic bodies are contemplated (e.g., a planar second metallic wafer 210). The metallic bodies 212 of the second metallic wafer 210 may be provided in a layout that corresponds to (e.g., mirrors) a layout of the die sites 102 and/or the vertical power semiconductor devices 120 of the semiconductor wafer 100. The second metallic wafer 210 may be a solid metallic piece (e.g., like the metallic wafer 110 of FIG. 1A) or may include the plurality of distinct metallic bodies 212 interconnected via a web framework (e.g., like the metallic wafer 110 of FIG. 1B). The second metallic wafer 210 may be formed from a sheet, plate, or other body of a metal, metal alloy, or other electrical conductor. For example, the second metallic wafer 210 may be formed from a sheet of copper, aluminum, a conductive alloy, etc. The sheet, plate, or other body may be stamped, etched, punched, or otherwise processed to produce the arrangement of the distinct metallic bodies 212, the web framework, and any other features of the second metallic wafer 210. The second metallic wafer 210 may have a thickness that is greater than 50 microns. In some examples, the second metallic wafer 210 has a thickness that is greater than 100 microns, e.g., up to 500 microns. The second metallic wafer 210 may be thicker than the metallic wafer 110. The metallic bodies 212 of the second metallic wafer 210 may have structures that are similar to those illustrated for the metallic bodies 112 of the metallic wafer 110 in FIG. 1C. Some of the metallic bodies 212 of the second metallic wafer 210 may include one or more vacuum openings 214 that extend at least partly through the metallic body 212, potentially providing improved suction during a pick-and-place process (e.g., from a vacuum duct).

In this example, first metallic bodies 112 (e.g., from the metallic wafer 110) are attached to each of the individual semiconductor dies 104 on the first side 100_{S1} of the semiconductor wafer 100. The second metallic wafer 210 is attached to a second, opposite side 100_{S2} of the semiconductor wafer 100. While FIG. 8 illustrates the semiconductor wafer 100 completely singulated into the individual semiconductor dies 104, the steps illustrated in FIG. 8 and subsequent figures may be completed on the unsingulated semiconductor wafer 100 (e.g., as in FIG. 2A) or the partially singulated semiconductor wafer 100 (e.g., as in FIG. 2B). In FIG. 8, the individual semiconductor dies 104 of the semiconductor wafer 100 are suspended by the frame 105, although other means of supporting the individual semiconductor dies 104 in the shape of the semiconductor wafer 100 for subsequent processing are contemplated. Additionally, while FIG. 8 illustrates separate first metallic bodies 112 that are attached to each of the individual semiconductor dies 104 (e.g., after completing the steps illustrated in FIG. 5), examples in which the second metallic wafer 210 is attached to the semiconductor wafer 100 before singulating the metallic wafer 110 into separate first metallic bodies 112 are contemplated.

Attaching the second metallic wafer 210 to the second side 100_{S2} of the semiconductor wafer 100 includes attaching a first contact surface 212_{S1} of a second metallic body 212 of the second metallic wafer 210 to the second load terminal 123 of the vertical power semiconductor device 120 of each die site 102. A second contact surface 212_{S2} opposite the first contact surface 212_{S1} of each second metallic body 212 forms a contact for the second load terminal 123 of the vertical power semiconductor device 120 attached to the second metallic body 212. In some examples, attaching the second metallic wafer 210 to the second side 100_{S2} of the semiconductor wafer 100 includes at least one of sintering, diffusion soldering, soldering, welding, adhering, gluing, etc. For example, a second metallic body 212 may be sintered, diffusion soldered, soldered, adhered, glued, etc. to the second load terminal 123 of a vertical power semiconductor device 120.

In this example, a single separate second metallic body 212 is attached to each individual semiconductor die 104, although examples in which multiple second metallic bodies 212 are attached to a single semiconductor die 104 are contemplated, similar to the example of the metallic bodies 112₁ and 112₂ of the metallic wafer 110 in FIG. 3C.

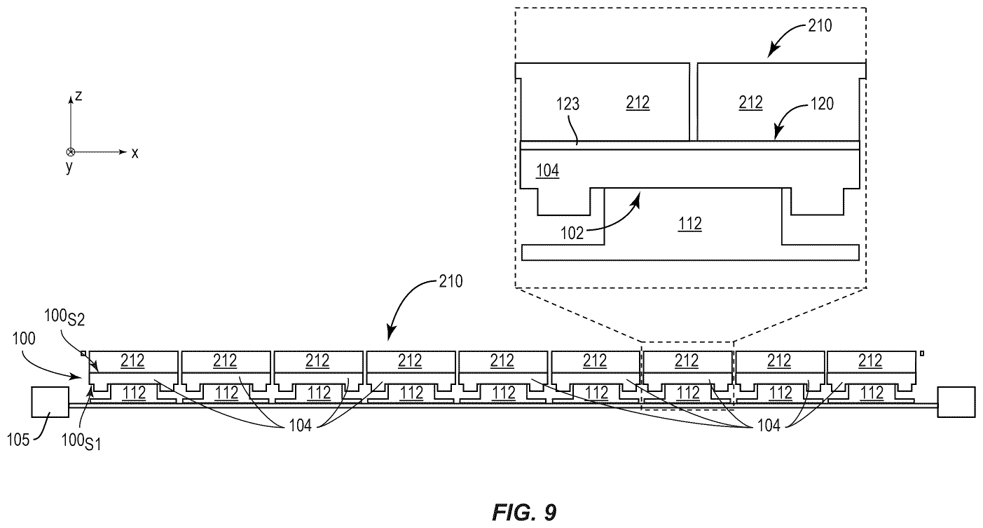

FIG. 9 illustrates singulating the second metallic wafer 210 into a plurality of separate second metallic bodies 212 in a method for attaching metallic bodies to thin semiconductor dies at the wafer level, according to an embodiment.

The second metallic wafer 210 is singulated after attaching the second metallic wafer 210 to the second side 100_{S2} of the semiconductor wafer 100 but before removing the individual semiconductor dies 104 from the semiconductor wafer 100. The separate second metallic bodies 212 remain attached to the individual semiconductor dies 104. Singulating the second metallic wafer 210 may be done using methods that are similar to those used to singulate the metallic wafer 110 into separate first metallic bodies 112, such as sawing, e.g., mechanical sawing or laser sawing, by etching, etc. In some examples, singulating the die sites 102 of the semiconductor wafer 100 into individual semiconductor dies 104 and singulating the second metallic wafer 210 into a plurality of separate second metallic bodies 212 that remain attached to the individual semiconductor dies 104 are done sequentially or simultaneously during the same singulation process (e.g., using the same saw, e.g., using different dicing wheels). In some examples, singulating the die sites 102 of the semiconductor wafer 100 into individual semiconductor dies 104, singulating the metallic wafer 110 into a plurality of separate first metallic bodies 112 that remain attached to the individual semiconductor dies 104, and singulating the second metallic wafer 210 into a plurality of separate second metallic bodies 212 that remain attached to the individual semiconductor dies 104 are done sequentially or simultaneously during the same singulation process (e.g., using the same saw, e.g., using different dicing wheels).

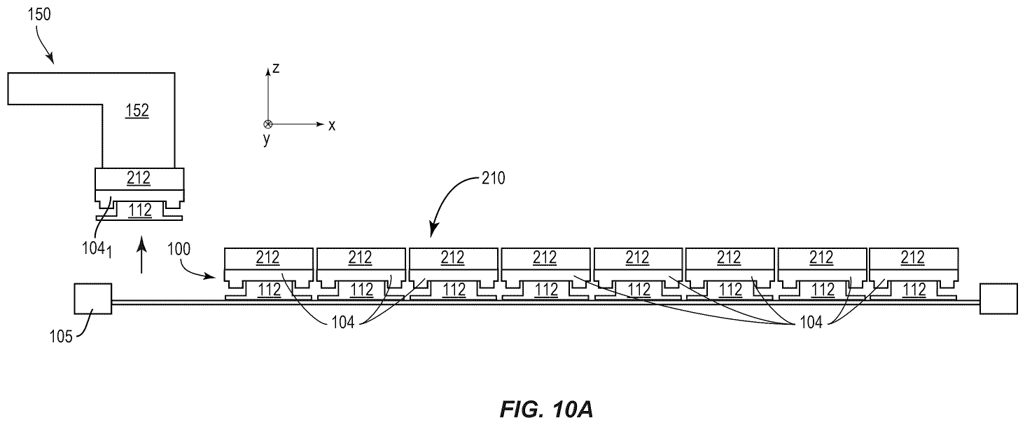

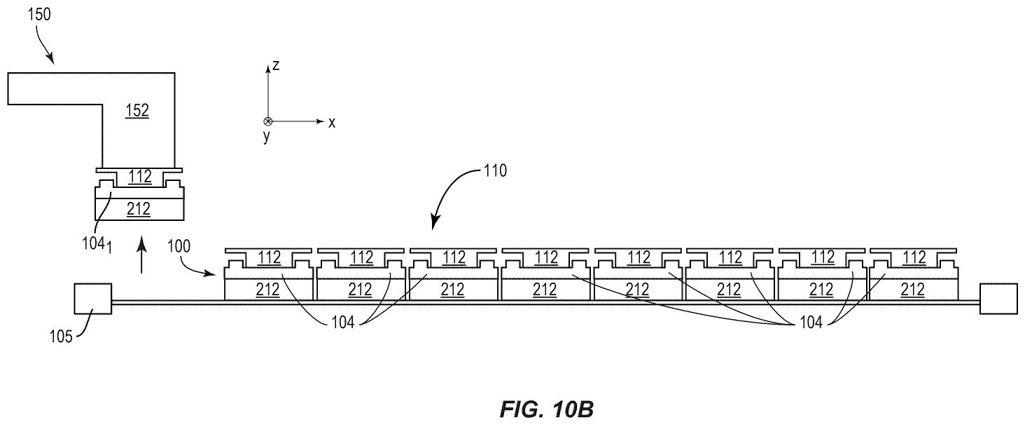

FIGS. 10A-10B illustrate removing an individual semiconductor die 104₁ from the semiconductor wafer 100 in a method for attaching metallic bodies to thin semiconductor dies at the wafer level, according to an embodiment.

One or more of the individual semiconductor dies 104₁ (e.g., the individual semiconductor die 104₁) may be picked and removed from the semiconductor wafer 100 after singulating the die sites 102 into individual semiconductor dies 104, after singulating the first metallic wafer 110 into a plurality of separate first metallic bodies 112, and after singulating the second metallic 210 wafer into a plurality of separate second metallic bodies 212. FIG. 10A illustrates picking the individual semiconductor die 104₁ by contacting the second metallic body 212 of the second metallic wafer 210 that is attached to the individual semiconductor die 104₁ with the component 152 of the pick and place machine 150 and removing the individual semiconductor die 104₁ from the semiconductor wafer 100. FIG. 10B illustrates picking the individual semiconductor die 104₁ by contacting the first metallic body 112 of the metallic wafer 110 that is attached to the individual semiconductor die 104₁ with the component 152 of the pick and place machine 150 and removing the individual semiconductor die 104₁ from the semiconductor wafer 100. More than one semiconductor die 104 may be picked and placed at the same time.

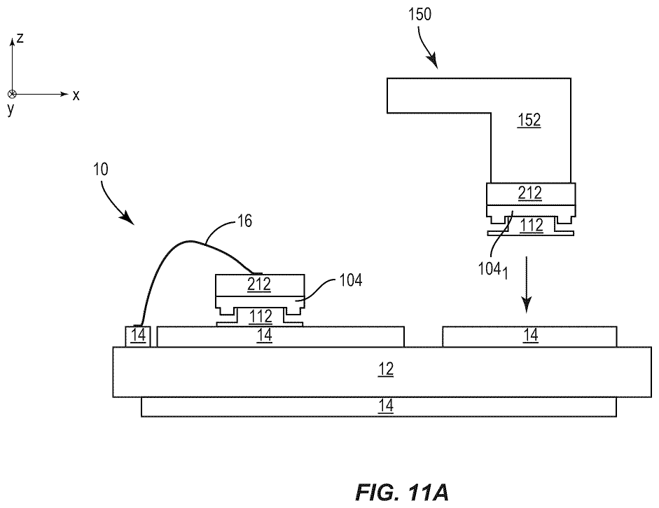

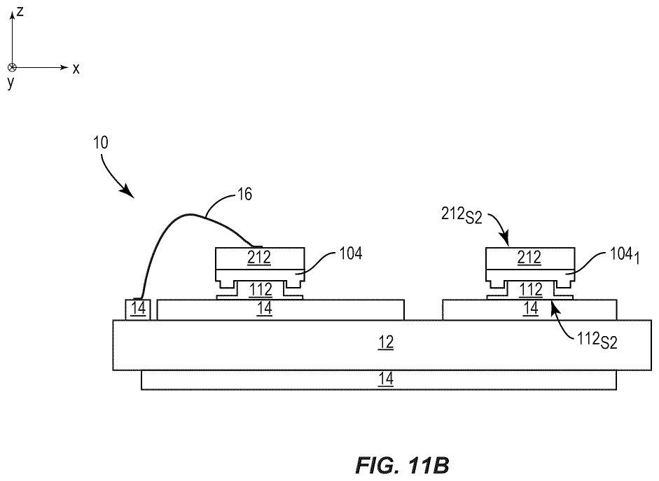

FIGS. 11A-11B illustrate placing the individual semiconductor die 104₁ from the semiconductor wafer 100 on a power semiconductor module 10 in a method for attaching metallic bodies to thin semiconductor dies at the wafer level, according to an embodiment.

FIG. 11A illustrates placing, with the pick and place machine 150, the individual semiconductor die 104₁ on a metallization layer 14 of the power semiconductor module 10. FIG. 11B illustrates attaching the individual semiconductor die 104₁ to the metallization layer 14 of the power semiconductor module 10. In this example, the individual semiconductor die 104₁ is picked by contacting the second metallic body 212 attached to the individual semiconductor die 104₁ with the component 152 of the pick and place machine 150, and the second contact surface 112_{S2} of the metallic body 112 attached to the individual semiconductor die 104₁ is attached to the metallization layer 14. In examples where the second contact surface 112_{S2} forms a contact for the first load terminal 121 of the vertical power semiconductor device 120 of the individual semiconductor die 104₁ (e.g., the first load terminal 121 of FIG. 3B), the first load terminal 121 is electrically coupled to the metallization layer 14 to which the first metallic body 112 is attached.

Examples in which the individual semiconductor die 104₁ is picked by contacting the first metallic body 112 attached to the individual semiconductor die 104₁ with the component 152 of the pick and place machine 150 and placed such that the second contact surface 212_{S2} of the second metallic body 212 attached to the individual semiconductor die 104₁ is attached to the metallization layer 14 are contemplated. In such examples, the second contact surface 212_{S2} may form a contact for the second load terminal 123 of the vertical power semiconductor device 120 of the individual semiconductor die 104₁, and the second load terminal 123 is thus electrically coupled to the metallization layer 14 to which the metallic body 212 is attached.

In the examples of FIGS. 11A and 11B, the first metallic body 112 and the second metallic body 212 may be attached to the power semiconductor module 10 (e.g., to a metallization layer 14) by diffusion soldering, soldering, or sintering.

The methods of FIGS. 10A-11B may be repeated for additional individual semiconductor dies 104 of the semiconductor wafer 100. Each additional individual semiconductor dies 104 may be placed on the power semiconductor module 10 or another module, assembly, structure, etc.

Although the present disclosure is not so limited, the following numbered examples demonstrate one or more aspects of the disclosure.

Example 1. A method, comprising: providing a semiconductor wafer comprising a plurality of die sites each including a vertical power semiconductor device, the semiconductor wafer having a thickness of 250 microns or less; attaching a metallic wafer to the semiconductor wafer, the metallic wafer having a similar shape as the semiconductor wafer; before or after attaching the metallic wafer to the semiconductor wafer, singulating the die sites into individual semiconductor dies; and after attaching the metallic wafer to the semiconductor wafer but before removing the individual semiconductor dies from the semiconductor wafer, singulating the metallic wafer into a plurality of separate metallic bodies that remain attached to the individual semiconductor dies.

Example 2. The method of example 1, wherein attaching the metallic wafer to the semiconductor wafer comprises attaching a first contact surface of a first metallic body of the metallic wafer to a first load terminal of the vertical power semiconductor device of each die site such that a second contact surface opposite the first contact surface of each first metallic body forms a contact for the first load terminal of the vertical power semiconductor device attached to the first metallic body.

Example 3. The method of example 2, wherein the first load terminal of the vertical power semiconductor device of each die site is one of a source terminal, an emitter terminal, a drain terminal, or a collector terminal.

Example 4. The method of example 2 or 3, wherein attaching the metallic wafer to the semiconductor wafer further comprises attaching a first contact surface of a second metallic body of the metallic wafer to a control terminal of the vertical power semiconductor device of each die site such that a second contact surface opposite the first contact surface of each second metallic body forms a contact for the control terminal of the vertical power semiconductor device attached to the second metallic body.

Example 5. The method of example 4, wherein the first load terminal of the vertical power semiconductor device of each die site is a source terminal or emitter terminal, and wherein the control terminal of the vertical power semiconductor device of each die site is a gate terminal.

Example 6. The method of any of examples 2 through 5, wherein one or more first metallic bodies of the metallic wafer comprise a vacuum opening that extends at least partly through the first metallic body.

Example 7. The method of any of examples 1 through 6, wherein, before singulating the metallic wafer into a plurality of separate metallic bodies that remain attached to the individual semiconductor dies, the metallic wafer is a solid metallic piece comprising a plurality of distinct metallic bodies formed in the solid metallic piece.

Example 8. The method of any of examples 1 through 6, wherein, before singulating the metallic wafer into a plurality of separate metallic bodies that remain attached to the individual semiconductor dies, the metallic wafer comprises a plurality of distinct metallic bodies interconnected via a web framework.

Example 9. The method of any of examples 1 through 8, wherein attaching the metallic wafer to the semiconductor wafer comprises at least one of sintering, diffusion soldering, or soldering.

Example 10. The method of any of examples 1 through 9, wherein the die sites are at least partially singulated into individual semiconductor dies before attaching the metallic wafer to the semiconductor wafer.

Example 11. The method of any of examples 1 through 10, further comprising: after attaching the metallic wafer to the semiconductor wafer but before removing the individual semiconductor dies from the semiconductor wafer, applying an encapsulant that encapsulates at least a part of each die site.

Example 12. The method of any of examples 1 through 11, wherein singulating the die sites into individual semiconductor dies and singulating the metallic wafer into a plurality of separate metallic bodies that remain attached to the individual semiconductor dies are done simultaneously during a same singulation process.

Example 13. The method of any of examples 1 through 12, further comprising: after singulating the die sites into individual semiconductor dies and after singulating the metallic wafer into a plurality of separate metallic bodies that remain attached to the individual semiconductor dies, picking one or more of the individual semiconductor dies by contacting a metallic body attached to a respective individual semiconductor die with a component of a pick and place machine and removing the respective individual semiconductor die from the semiconductor wafer.

Example 14. The method of example 13, further comprising: after removing the respective individual semiconductor die from the semiconductor wafer, placing, with the pick and place machine, the respective individual semiconductor die on a power semiconductor module.

Example 15. The method of example 14, wherein placing the respective individual semiconductor on the power semiconductor module comprises attaching the respective individual semiconductor die to the power semiconductor module by diffusion soldering, soldering, or sintering.

Example 16. The method of any of examples 1 through 15, wherein attaching a metallic wafer to the semiconductor wafer comprises attaching a first metallic wafer to a first side of the semiconductor wafer, wherein singulating the metallic wafer into a plurality of separate metallic bodies that remain attached to the individual semiconductor dies comprises singulating the first metallic wafer into a plurality of separate first metallic bodies that remain attached to the individual semiconductor dies, and wherein the method further comprises: attaching a second metallic wafer to a second, opposite side of the semiconductor wafer, the second metallic wafer having a similar shape as the semiconductor wafer and the first metallic wafer; and after attaching the second metallic wafer to the second side of the semiconductor wafer but before removing the individual semiconductor dies from the semiconductor wafer, singulating the second metallic wafer into a plurality of separate second metallic bodies that remain attached to the individual semiconductor dies.

Example 17. The method of example 16, wherein attaching the second metallic wafer to the second side of the semiconductor wafer comprises attaching a first contact surface of a second metallic body of the second metallic wafer to a second load terminal of the vertical power semiconductor device of each die site such that a second contact surface opposite the first contact surface of each second metallic body forms a contact for the second load terminal of the vertical power semiconductor device attached to the second metallic body.

Example 18. The method of example 17, wherein the second load terminal of the vertical power semiconductor device of each die site is one of a source terminal, an emitter terminal, a drain terminal, or a collector terminal.

Example 19. The method of example 17 or 18, wherein one or more second metallic bodies of the second metallic wafer comprise a vacuum opening that extends at least partly through the second metallic body.

Example 20. The method of any of examples 16 through 19, wherein attaching the second metallic wafer to the second side of the semiconductor wafer comprises at least one of sintering, diffusion soldering, or soldering.

Example 21. The method of any of examples 16 through 20, further comprising: after singulating the die sites into individual semiconductor dies, after singulating the first metallic wafer into a plurality of separate first metallic bodies, and after singulating the second metallic wafer into a plurality of separate second metallic bodies, picking one or more of the individual semiconductor dies by contacting the first metallic body or the second metallic body attached to a respective individual semiconductor die with a component of a pick and place machine and removing the respective individual semiconductor die from the semiconductor wafer.

Example 22. The method of example 21, further comprising: after removing the respective individual semiconductor die from the semiconductor wafer, placing, with the pick and place machine, the respective individual semiconductor die on a semiconductor module.

Example 23. The method of example 22, wherein placing the respective individual semiconductor on the semiconductor module comprises attaching the respective individual semiconductor die to the semiconductor module by diffusion soldering, soldering, or sintering.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
providing a semiconductor wafer comprising a plurality of die sites each including a vertical power semiconductor device, the semiconductor wafer having a thickness of 250 microns or less;
attaching a metallic wafer to the semiconductor wafer, the metallic wafer having a similar shape as the semiconductor wafer;
before or after attaching the metallic wafer to the semiconductor wafer, singulating the die sites into individual semiconductor dies; and
after attaching the metallic wafer to the semiconductor wafer but before removing the individual semiconductor dies from the semiconductor wafer, singulating the metallic wafer into a plurality of separate metallic bodies that remain attached to the individual semiconductor dies.

2. The method of claim 1, wherein attaching the metallic wafer to the semiconductor wafer comprises attaching a first contact surface of a first metallic body of the metallic wafer to a first load terminal of the vertical power semiconductor device of each die site such that a second contact surface opposite the first contact surface of each first metallic body forms a contact for the first load terminal of the vertical power semiconductor device attached to the first metallic body.

3. The method of claim 2, wherein the first load terminal of the vertical power semiconductor device of each die site is one of a source terminal, an emitter terminal, a drain terminal, or a collector terminal.

4. The method of claim 2, wherein attaching the metallic wafer to the semiconductor wafer further comprises attaching a first contact surface of a second metallic body of the metallic wafer to a control terminal of the vertical power semiconductor device of each die site such that a second contact surface opposite the first contact surface of each second metallic body forms a contact for the control terminal of the vertical power semiconductor device attached to the second metallic body.

5. The method of claim 4,
wherein the first load terminal of the vertical power semiconductor device of each die site is a source terminal or emitter terminal, and
wherein the control terminal of the vertical power semiconductor device of each die site is a gate terminal.

6. The method of claim 2, wherein one or more first metallic bodies of the metallic wafer comprise a vacuum opening that extends at least partly through the first metallic body.

7. The method of claim 1, wherein, before singulating the metallic wafer into a plurality of separate metallic bodies that remain attached to the individual semiconductor dies, the metallic wafer is a solid metallic piece comprising a plurality of distinct metallic bodies formed in the solid metallic piece.

8. The method of claim 1, wherein, before singulating the metallic wafer into a plurality of separate metallic bodies that remain attached to the individual semiconductor dies, the metallic wafer comprises a plurality of distinct metallic bodies interconnected via a web framework.

9. The method of claim 1, wherein attaching the metallic wafer to the semiconductor wafer comprises at least one of sintering, diffusion soldering, or soldering.

10. The method of claim 1, wherein the die sites are at least partially singulated into individual semiconductor dies before attaching the metallic wafer to the semiconductor wafer.

11. The method of claim 1, further comprising:
after attaching the metallic wafer to the semiconductor wafer but before removing the individual semiconductor dies from the semiconductor wafer, applying an encapsulant that encapsulates at least a part of each die site.

12. The method of claim 1, wherein singulating the die sites into individual semiconductor dies and singulating the metallic wafer into a plurality of separate metallic bodies that remain attached to the individual semiconductor dies are done simultaneously during a same singulation process.

13. The method of claim 1, further comprising:
after singulating the die sites into individual semiconductor dies and after singulating the metallic wafer into a plurality of separate metallic bodies that remain attached to the individual semiconductor dies, picking one or more of the individual semiconductor dies by contacting a metallic body attached to a respective individual semiconductor die with a component of a pick and place machine and removing the respective individual semiconductor die from the semiconductor wafer.

14. The method of claim 13, further comprising:
after removing the respective individual semiconductor die from the semiconductor wafer, placing, with the pick and place machine, the respective individual semiconductor die on a power semiconductor module.

15. The method of claim 14, wherein placing the respective individual semiconductor on the power semiconductor module comprises attaching the respective individual semiconductor die to the power semiconductor module by diffusion soldering, soldering, or sintering.

16. The method of claim 1,
wherein attaching a metallic wafer to the semiconductor wafer comprises attaching a first metallic wafer to a first side of the semiconductor wafer,
wherein singulating the metallic wafer into a plurality of separate metallic bodies that remain attached to the individual semiconductor dies comprises singulating the first metallic wafer into a plurality of separate first metallic bodies that remain attached to the individual semiconductor dies, and
wherein the method further comprises:
attaching a second metallic wafer to a second, opposite side of the semiconductor wafer, the second metallic wafer having a similar shape as the semiconductor wafer and the first metallic wafer; and
after attaching the second metallic wafer to the second side of the semiconductor wafer but before removing the individual semiconductor dies from the semiconductor wafer, singulating the second metallic wafer into a plurality of separate second metallic bodies that remain attached to the individual semiconductor dies.

17. The method of claim 16, wherein attaching the second metallic wafer to the second side of the semiconductor wafer comprises attaching a first contact surface of a second metallic body of the second metallic wafer to a second load terminal of the vertical power semiconductor device of each die site such that a second contact surface opposite the first contact surface of each second metallic body forms a contact for the second load terminal of the vertical power semiconductor device attached to the second metallic body.

18. The method of claim 17, wherein the second load terminal of the vertical power semiconductor device of each die site is one of a source terminal, an emitter terminal, a drain terminal, or a collector terminal.

19. The method of claim 17, wherein one or more second metallic bodies of the second metallic wafer comprise a vacuum opening that extends at least partly through the second metallic body.

20. The method of claim 16, wherein attaching the second metallic wafer to the second side of the semiconductor wafer comprises at least one of sintering, diffusion soldering, or soldering.

21. The method of claim 16, further comprising:
after singulating the die sites into individual semiconductor dies, after singulating the first metallic wafer into a plurality of separate first metallic bodies, and after singulating the second metallic wafer into a plurality of separate second metallic bodies, picking one or more of the individual semiconductor dies by contacting the first metallic body or the second metallic body attached to a respective individual semiconductor die with a component of a pick and place machine and removing the respective individual semiconductor die from the semiconductor wafer.

22. The method of claim 21, further comprising:
after removing the respective individual semiconductor die from the semiconductor wafer, placing, with the pick and place machine, the respective individual semiconductor die on a semiconductor module.

23. The method of claim 22, wherein placing the respective individual semiconductor on the semiconductor module comprises attaching the respective individual semiconductor die to the semiconductor module by diffusion soldering, soldering, or sintering.
